(19) United States
(12) Patent Application Publication
(10) Pub. No.: US 2025/0107161 A1
(43) Pub. Date: Mar. 27, 2025

(54) DELTA-LAYER TUNNEL JUNCTION DEVICE WITH TWO OHMIC CONDUCTIVITY REGIMES

(71) Applicant: National Technology & Engineering Solutions of Sandia, LLC, Albuquerque, NM (US)

(72) Inventors: Juan Pedro Mendez Granado, Albuquerque, NM (US); Denis Mamaluy, Albuquerque, NM (US)

(21) Appl. No.: 18/371,531

(22) Filed: Sep. 22, 2023

(51) Int. Cl. H01L 29/66; H01L 29/06; H01L 29/86

(52) U.S. Cl. CPC H10D 48/383; H10D 1/40; H10D 48/021; H10D 62/124

(57) ABSTRACT

A semiconductor device having first and second conductivity regimes is provided. The device comprises a substrate body, a source formed along a first sidewall of the substrate body, and a drain formed along a second sidewall of the substrate body. The device comprises first and second delta layers disposed on the substrate body and separated by a gap. The first delta layer is in contact with the source and the second delta layer is in contact with the drain. The device comprises a cap disposed over the first and second delta layers. The device has the first conductivity regime responsive to a first voltage between the drain and the source and has the second conductivity regime responsive to a second voltage between the drain and the source.

### STATEMENT OF GOVERNMENT INTEREST

This invention was made with United States Government support under Contract No. DE-NA0003525 awarded by the United States Department of Energy/National Nuclear Security Administration. The United States Government has certain rights in this invention.

### BACKGROUND

### 1. Field

The disclosure relates generally to semiconductor devices, and more specifically to a delta layer tunnel junction device with two conductivity regimes.

### 2. Description of the Related Art

A voltage dependent resistor, also known as a variable resistor, or a varistor, is an electronic component with an electrical resistance that varies with the applied voltage. At low voltages, the varistor has a high electrical resistance which decreases as the voltage is raised. Variable resistors are used as control or compensation elements in circuits to provide optimal operating conditions and to protect against excessive transient voltages. When used as protection devices, variable resistors shunt current created by the excessive voltage away from sensitive components.

Variable resistors are typically constructed by connecting two rectifiers, such as copper-oxide or germanium-oxide rectifiers in an anti-parallel configuration. Modern variable resistors are primarily based on sintered ceramic metal-oxide materials which exhibit directional behavior only on a microscopic scale. However, the dimensions of the metal-oxide variable resistors are relatively large (e.g., >1 micrometer), which limits their application in nano-scale electronic circuits.

### SUMMARY

An illustrative embodiment provides a semiconductor device having first and second conductivity regimes. The device comprises a substrate body, a source formed along a first sidewall of the substrate body, and a drain formed along a second sidewall of the substrate body. The device comprises first and second delta layers disposed on the substrate body and separated by a gap. The first delta layer is in contact with the source and the second delta layer is in contact with the drain. The device comprises a cap disposed over the first and second delta layers. The device has the first conductivity regime responsive to a first voltage between the drain and the source and has the second conductivity regime responsive to a second voltage between the drain and the source.

Another illustrative embodiment provides a semiconductor device having first and second resistive states. The device comprises a substrate body. A source is formed along a first sidewall of the substrate body, and a drain is formed along a second sidewall of the substrate body. The device comprises first and second delta layers disposed on the substrate body and separated by a gap. The first delta layer is in contact with the source and the second delta layer is in contact with the drain. The device comprises a cap disposed over the first and second delta layers. The semiconductor device has the first resistive state responsive to a first voltage between the drain and the source and has the second resistive state responsive to a second voltage between the drain and the source.

Another illustrative embodiment provides a method for fabricating a semiconductor device having first and second conductivity regimes. The method comprises forming a substrate body using a semiconductor material. The method comprises doping the substrate body to introduce controlled amounts of dopants for controlling electrical properties of the device and passivating a surface of the substrate body. The method comprises forming first and second delta layers on the substrate body. The first and second delta layers are separated by a gap. The method comprises depositing a cap over the first and second delta layers to embed the delta layers between the substrate body and the cap. The method comprises forming a source in a first region of the substrate body and forming a drain in a second region of the substrate body. The source is in contact with the first delta layer and the drain is in contact with the second delta layer.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 illustrates a cross-sectional view of delta layer tunnel junction device in accordance with an illustrative embodiment;

FIG. 2 illustrates a perspective view of a delta layer tunnel junction device in accordance with an illustrative embodiment;

FIG. 3 illustrates tunneling current vs. tunnel gap length of the devices of FIGS. 1 and 2;

FIG. 4 illustrates current vs. voltage and differential resistance of the devices of FIGS. 1 and 2;

FIG. 5A and FIG. 5B illustrate a plot of energy levels along an x-axis of the device of FIG. 2; and

FIG. 6 is a flowchart of a process for fabricating a device in accordance with an illustrative embodiment.

### DETAILED DESCRIPTION

The illustrative embodiments provide a variable resistance semiconductor device with a delta layer tunnel junction. The semiconductor device has two conductivity regimes. The semiconductor device includes a source and a drain but does not include a gate. Because the semiconductor device includes only two electrodes and does not require sintered metal-oxide materials, manufacturing complexity and costs are reduced.

According to the illustrative embodiments, the variable resistance semiconductor device has a first conductivity regime responsive to a first voltage between the drain and the source and has a second conductivity regime responsive to a second voltage between the drain and the source. The second voltage is higher than the first voltage. A current between the drain and the source in the second conductivity state is higher than a current between the drain and the source in the first conductivity regime.

Because the semiconductor device has two conductivity regimes, the device also has two resistive states. The device has a first resistive state responsive to a first voltage between the drain and the source and has a second resistive state responsive to a second voltage between the drain and the source. The first resistance is higher than the second resistance. Between first and second voltages, there is a transition state over which the resistance falls rapidly. The device has advantages of simplicity of manufacturing and scaling for Si-compatible nano-scale circuits.

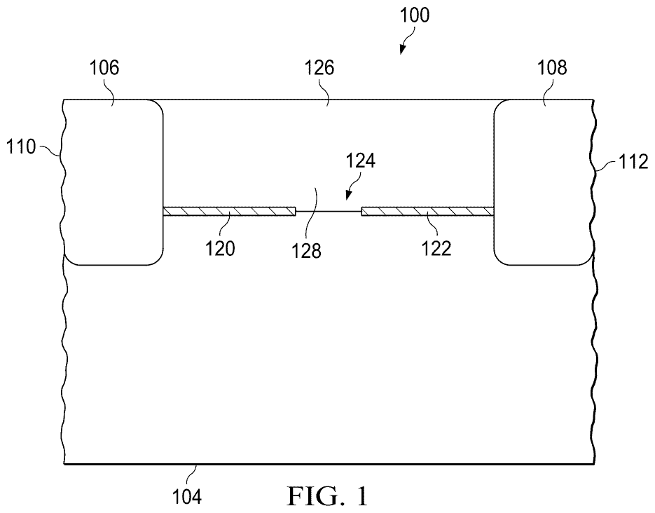

FIG. 1 illustrates a cross-sectional view of delta layer tunnel junction device 100 in accordance with an illustrative embodiment. Device 100 includes substrate body 104 which acts as a foundation and provides structural support to Device 100. In one example implementation, substrate body 104 is formed using a crystal silicon wafer, which serves as the base material for the fabrication of device 100. Substrate body 104 may undergo a doping step, which involves introducing controlled amounts of specific impurities (dopants) to control electrical properties such as the conductivity of substrate body 104. In one illustrative embodiment, substrate body 104 is doped with a p-type dopant such as boron (B).

Substrate body 104 maintains the physical integrity of the structure of device 100 and prevents mechanical stress and deformation. Also, substrate body 104 serves as a reference potential and may be electrically connected a reference voltage (e.g., ground).

Device 100 includes source 106 and drain 108. Source 106 may be formed in a region along sidewall 110 of substrate body 104. Drain 108 may be formed in a region along sidewall 112 of substrate body 104. In some example embodiments, source 106 and drain 108 may be formed by heavily doping regions of substrate body 104 (e.g., Si). Thus, source 106 and drain 108 may be formed using the same semiconductor material as substrate body 104 but with a much higher level of doping. In some example embodiments, source 106 and drain 108 may be made of a metal or silicide contacts.

Device 100 includes first delta layer 120 and second delta layer 122 disposed on substrate body 104. First delta layer 120 is in contact with source 106, and second delta layer 122 is in contact with drain 108. First delta layer 120 and second delta layer 122 are separated by gap 124. In some example embodiments, first delta layer 120 and second delta layer 122 are formed by thin layers of phosphorus. In some example embodiments, techniques such as atomic precision advance manufacturing (APAM) or photolithography may be used to form first delta layer 120 and second delta layer 122.

Device 100 includes cap 126 disposed over first delta layer 120 and second delta layer 122. Cap 126 is made of the same semiconductor material as substrate body 104. Thus, first delta layer 120 and second delta layer 122 extend from source 106 and drain 108, respectively, and are embedded between substrate body 104 and substrate cap 126. In one illustrative embodiment, cap 126 is doped with a p-type dopant such as boron (B).

First delta layer 120 and second delta layer 122 form tunnel junction 128 near gap 124. Tunnel junction 128 is a structure that facilitates controlled tunneling of individual electrons between source 106 and drain 108. Due to a quantum mechanical phenomenon, electrons can tunnel (i.e., pass) through tunnel junction 128 that would be normally impassable in classical mechanics. In a semiconductor device, tunneling is exploited to allow controlled transport of electrons.

Device 100 may be packaged as an integrated circuit (IC) (not shown in FIG. 1). Bond wires made of gold, aluminum or other suitable conductor can be used to connect source 106 and drain 108 to bonding pads on a lead-frame (not shown in FIG. 1). The bond wires establish electrical connections between device 100 and external circuitry. In some example embodiments, device 100 and the bond wires can be encapsulated in a protective material such as epoxy resin or a plastic compound.

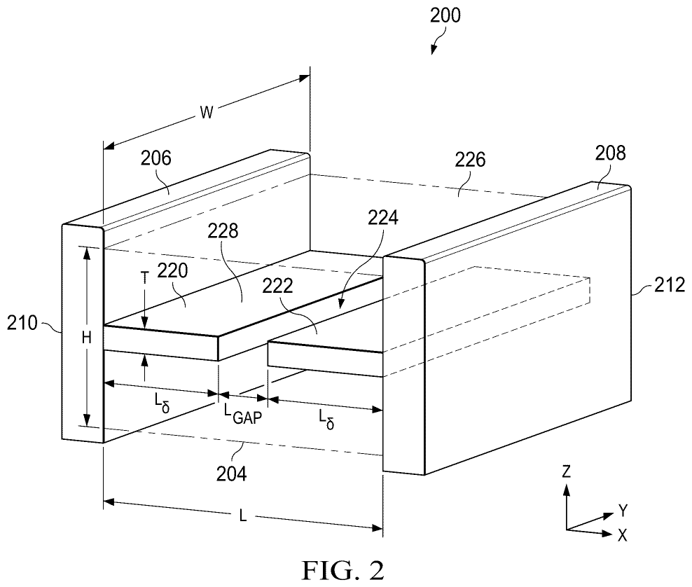

FIG. 2 illustrates a perspective view of delta layer tunnel junction device 200 in accordance with an illustrative embodiment. Device 200 includes substrate body 204 which acts as a foundation and provides structural support to device 200. Substrate body 204 may be formed using a semiconductor material such as silicon (Si) which may be doped with a dopant such as boron (B).

Device 200 includes source 206 and drain 208. Source 206 may be formed in a region along sidewall 210 of substrate body 204. Drain 208 may be formed in a region along sidewall 212 of substrate body 204. In some example embodiments, source 206 and drain 208 may be formed by heavily doping regions of substrate body 204 (e.g., Si). In other example embodiments, source 206 and drain 208 may be formed by a metal or silicide contacts.

Device 200 includes first delta layer 220 and second delta layer 222 disposed on substrate body 204. First delta layer 220 is in contact with source 206, and second delta layer 222 is in contact with drain 208. First delta layer 220 and second delta layer 222 are separated by gap 224. In some example embodiments, first delta layer 220 and second delta layer 222 are formed by thin layers of phosphorus.

Device 200 includes cap 226 disposed over first delta layer 220 and second delta layer 222. First delta layer 220 and second delta layer 222 extend from source 206 and drain 208, respectively, and are embedded between substrate body 204 and cap 226. In one illustrative embodiment, cap 226 is doped with a p-type dopant such as boron (B).

First and second delta layers 220 and 222 form tunnel junction 228 near gap 224. Tunnel junction 228 is a structure that facilitates controlled tunneling of individual electrons between source 206 and drain 208.

In the illustrative embodiment of FIG. 2, device 200 has the following dimensions: (1) length L, which is defined as the distance between source 206 and drain 208; (2) height H, which is defined as the height of source 206 or drain 208; (3) tunnel gap L_{GAP} which is defined as the length of gap 224; (4) delta length L_{DELTA}, which is defined as the length of the delta layers; and (5) thickness t, which is defined as the thickness of the delta layers.

In some example embodiments, L_{GAP}, L_{DELTA}, and thickness t can be controlled to tune electrical properties of device 200.

In one illustrative embodiment, L is around 40 nm, H is around 8 nm, the thickness of the delta layers is between 0.2 nm and 5 nm, and L_{GAP} is between 7 nm and 20 nm.

A bias voltage V (e.g., around 100 mV to around 1 V) is applied between drain 208 and source 206. In response to V, a tunneling current/flows between drain 208 and source 206.

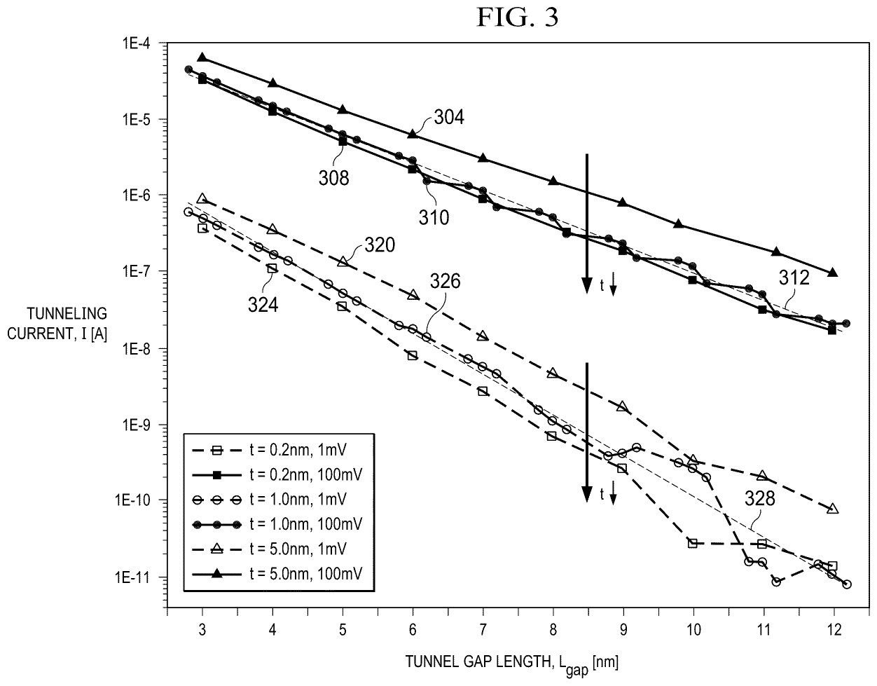

FIG. 3 illustrates plots of I vs. L_{GAP} of device 200 with a fixed sheet doping density. In the present disclosure, a fixed sheet doping density indicates that the total charge density of a sheet is constant.

More specifically, FIG. 3 shows I vs. L_{GAP} in a logarithmic scale for different delta layer thickness t and applied bias voltages: V=1 mV and V=100 mV. Plot 304 represents I vs. L_{GAP} for t=5 nm and V=100 mV. Plot 308 represents I vs. L_{GAP} for t=0.2 nm and V=100 mV. Plot 310 represents/vs. L_{GAP} for t=1.0 nm and V=100 mV. Plot 312 represents a least square fit for plot 310.

Plot 320 represents I vs. L_{GAP} for t=5.0 nm and V=1 mV. Plot 324 represents I vs. L_{GAP} for t=0.2 nm and V=1 mV. Plot 326 represents I vs. L_{GAP} for t=1.0 nm and V=1 mV. Plot 328 represents a least square fit for plot 326.

As shown in FIG. 3, the current I decreases as the delta layer thickness t increases for a fixed sheet doping density. The overall I vs L_{GAP} trend is exponential for gap lengths L_{GAP}=0 . . . , 12 nm, following ln(I)≈ln(I_{Lgap=0})−L_{gap}/B_{voltage}, where I_{Lgap}=0 is the current when L_{GAP}=0, L_{GAP} is the tunnel gap length, and B_{voltage} is a proportional constant related to a barrier height. However, a deviation from the exponential trend can be observed for large tunnel gaps (e.g., L_{GAP}>7 nm) and V=1 mV (dashed lines in FIG. 3). For V=100 mV (continuous lines in FIG. 3), the overall trend is exponential, thus indicating two conductivity regimes for the delta layer tunnel junction: low and high-conductivity regimes.

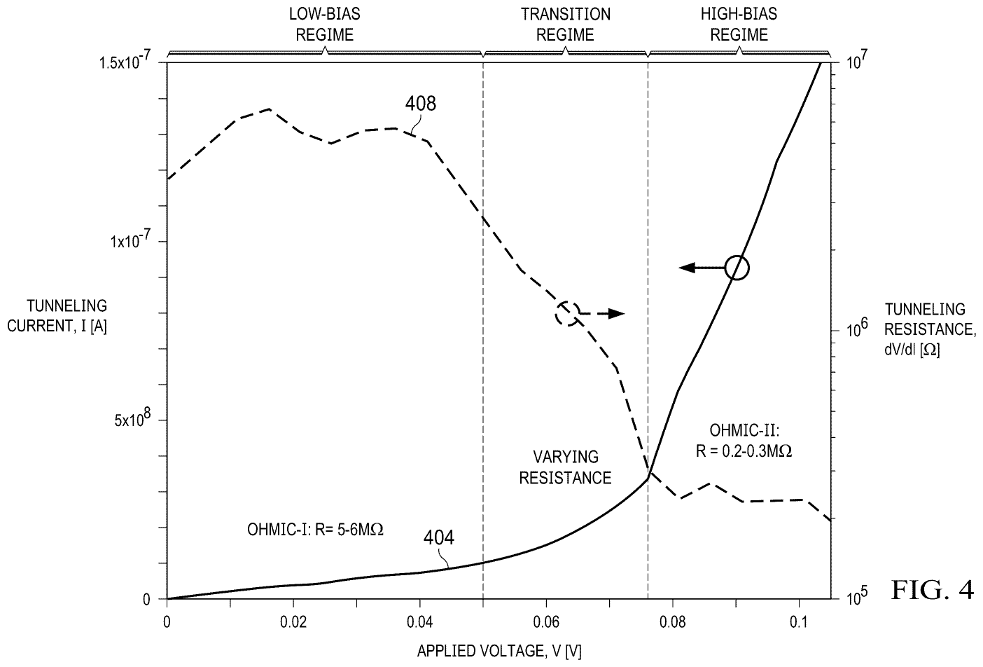

FIG. 4 illustrates plot 404 of current I vs. voltage V and plot 408 of differential resistance (dV/dI) plot 408 of device 200 for L_{GAP}=10 nm and thickness t=1 nm, and sheet doping density of 10¹⁴ cm⁻² of the delta layers. As shown in FIG. 4, at low voltages (e.g., between 0 V and 0.05 V), resistance plot 408 is approximately around 5-6 mega-ohms. However, at high voltages (e.g., >0.08 V), resistance plot 408 drops to approximately around 0.2-0.3 mega-ohms.

In FIG. 4, I vs. V illustrates two distinct conductivity regimes of device 200. As voltage V is increased from 0 V to around 50 mV, current I rises linearly at a slow rate from 0 A to around 10 nA. However, as V is increased from 0.075 V to 0.1V, the current rises sharply from 30 nA to 140 nA.

Thus, device 200 has a first conductivity regime responsive to a first voltage between drain 208 and source 206 and has a second conductivity regime responsive to a second voltage between drain 208 and source 206. The second voltage is higher than the first voltage. In some illustrative embodiments, the first voltage is between 0 V and 0.05 V, and the second voltage is between 0.075V and 0.11 V. A current between drain 208 and source 206 in the second conductivity state is higher than a current between drain 208 and source 206 in the first conductivity state.

Because device 200 has two conductivity regimes, device 200 also has two resistive states. Device 200 has a first resistive state responsive to a first voltage between drain 208 and source 206 and has a second resistive state responsive to a second voltage between drain 208 and source 206. The first resistance is higher than the second resistance. Between first and second voltages (e.g., between 0.05V and 0.075V), there is a transition state over which the resistance falls rapidly.

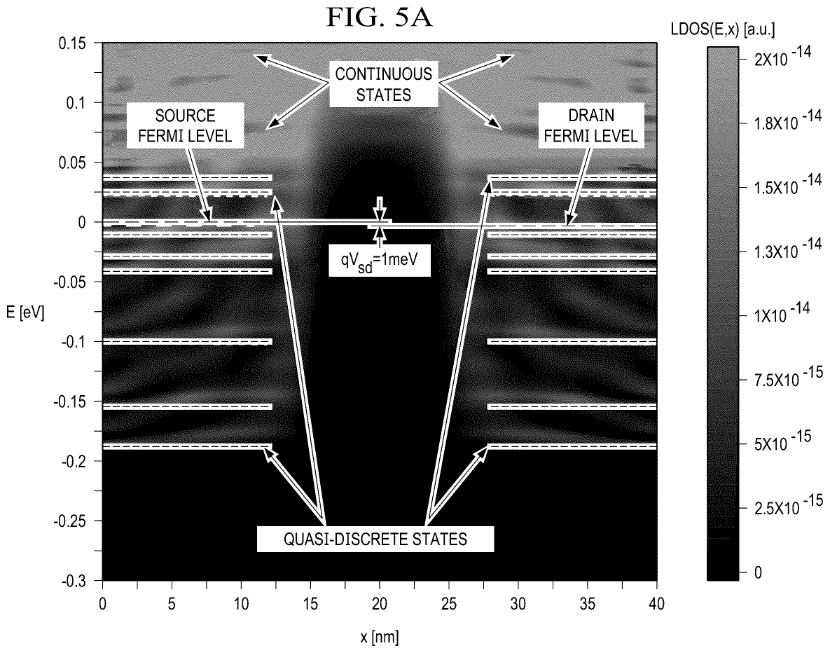

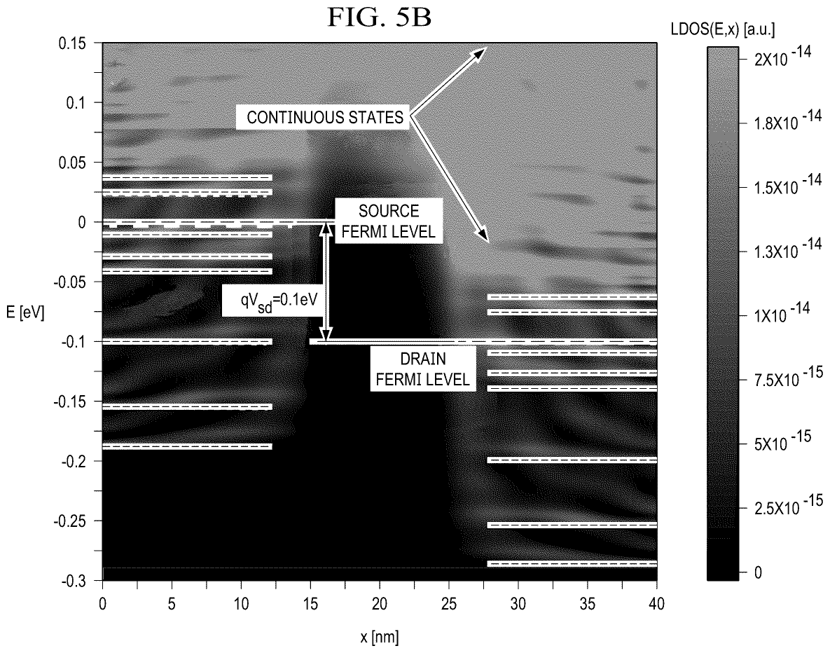

FIGS. 5A and 5B illustrate energy levels along an x-axis in device 200. The energy levels are also known as local density of states (LDOS (x, E)). In FIGS. 5A and 5B, states between x=0 nm and x=15 nm correspond to a first delta layer region, states between x=25 nm and x=40 nm correspond to a second delta layer region, and states between x=15 nm and x=25 nm correspond to a gap between the delta layer regions. The source Fermi level and drain Fermi level correspond to the Fermi levels of the source and drain, respectively.

At very low temperatures, states below the Fermi level are occupied by electrons and the states above the Fermi level are unoccupied. As the temperature increases, some states above the Fermi level start to be occupied to the detriment of the states below the Fermi level. It is assumed that only the states below the Fermi level are occupied by the electrons. In the delta layer regions (e.g., between x=0 nm and x=15 nm and between x=25 nm and x=40 nm), the low-energy LDOS (x, E) are strongly quantized, indicated by dashed lines, for energies below the Fermi level and approximately up to 50 meV above the Fermi level. For high energies (e.g., above 50 meV), the LDOS (x,E) are continuous in space-energy, and as such these states are not quantized.

In equilibrium, the Fermi level is constant across the device, thus the source and drain Fermi levels are equal. As a reference, the drain and source Fermi levels are set to zero in equilibrium. When a positive bias voltage V is applied to the drain (the source contact is grounded), the Fermi level of the drain is shifted down a magnitude value of V. As the second delta layer is ohmic connected to the drain, the states in the second delta layers are also shifted down. As a result of the Fermi level differences between the source and the drain, electrons start to flow from the source to the drain by tunneling from occupied states in the first delta layer region to unoccupied states in the second delta layer region in the vicinity of tunnel junction 228. The unoccupied states correspond to the state with energies in a range between the source and drain Fermi levels.

When the applied bias voltage V is small (e.g., <0.05V), only unoccupied quantized states in the second delta layer (i.e., only those with energies above the drain Fermi level) are shifted down to energies below the source Fermi level. Thus, for a low bias, tunneling only occurs from occupied quasi-discrete states to unoccupied quasi-discrete states, and as consequence tunneling is less plausible and, thus, the tunneling resistance is high.

When the applied bias voltage V is high (e.g., >0.075V), not only unoccupied quantized states in the second delta layer region are shifted down to energies below the source Fermi level, but also some continuum states. Thus, the tunneling not only occurs from occupied quasi-discrete states to unoccupied quasi-discrete states, but also to continuum states, and as a consequence, tunneling is more plausible and, thus, the tunneling resistance is lower.

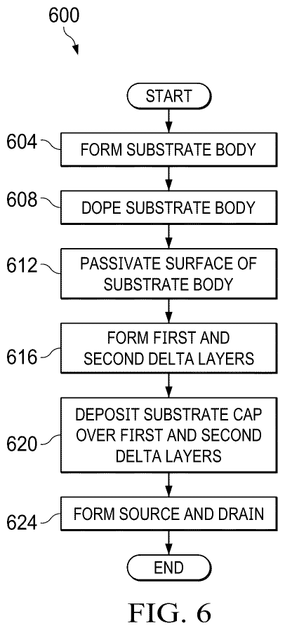

With reference next to FIG. 6, a flowchart of process 600 for fabricating device 100 or device 200 is depicted in accordance with an illustrative embodiment. A substrate body (e.g., substrate body 104) is formed using a semiconductor material such as silicon (step 604). In one example implementation, the substrate body is formed using a crystal silicon wafer, which serves as the base material for the fabrication of a charge-sensing device. The substrate body may undergo a doping step (step 608). Doping involves introducing controlled amounts of specific impurities (dopants) to control electrical properties such as the conductivity of the substrate body.

The surface of the substrate body is then passivated with hydrogen atoms (step 612). In some example embodiments, passivation of the substrate body may involve exposing the surface to hydrogen gas.

Next, first and second delta layers are formed on the substrate body (step 616). In some example implementations, the delta layers are formed by removing the hydrogen atoms from selected surface areas of the substrate body and depositing a layer of phosphorus on the selected surface areas. A cap (e.g., cap 126) is deposited over the first and second delta layers (step 620). The cap is made of the same semiconductor material as the substrate body. Thus, the delta layers are embedded between the substrate body and the cap.

A source (e.g., source 106) is formed in a region along a first sidewall of the substrate body, and a drain (e.g., drain 108) is formed in a region along a second sidewall of the substrate body (step 624). In some example embodiments, the source and the drain may be formed by heavily doping regions of the substrate body, or they can be made of a metal or silicide contacts.

The first delta layer (e.g., delta layer 120) is in contact with the source, and the second delta layer (e.g., delta layer 122) is in contact with the drain. The first and second delta layers are separated by a gap (e.g., gap 124). The length of the gap can be varied by increasing or decreasing the length of the delta layers.

As used herein, the phrase “a number” means one or more. The phrase “at least one of”, when used with a list of items, means different combinations of one or more of the listed items may be used, and only one of each item in the list may be needed. In other words, “at least one of” means any combination of items and number of items may be used from the list, but not all of the items in the list are required. The item may be a particular object, a thing, or a category.

For example, without limitation, “at least one of item A, item B, or item C” may include item A, item A and item B, or item C. This example also may include item A, item B, and item C or item B and item C. Of course, any combinations of these items may be present. In some illustrative examples, “at least one of” may be, for example, without limitation, two of item A; one of item B; and ten of item C; four of item B and seven of item C; or other suitable combinations.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks may be implemented as program code.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component. Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A semiconductor device having first and second conductivity regimes, comprising:
a substrate body;
a source formed along a first sidewall of the substrate body;
a drain formed along a second sidewall of the substrate body;
first and second delta layers disposed on the substrate body and separated by a gap, wherein the first delta layer is in contact with the source and the second delta layer is in contact with the drain; and
a cap disposed over the first and second delta layers,
wherein the semiconductor device has the first conductivity regime responsive to a first voltage between the drain and the source and has the second conductivity regime responsive to a second voltage between the drain and the source.

2. The semiconductor device of claim 1, wherein the second voltage is higher than the first voltage.

3. The semiconductor device of claim 1, wherein a current between the drain and the source is higher in the second conductivity regime than a current between the drain and the source in the first conductivity regime.

4. The semiconductor device of claim 1, wherein the first voltage is between 0 V and 0.05 V, and wherein the second voltage is between 0.075 V and 0.11 V.

5. The semiconductor device of claim 1, wherein the first and second delta layers are embedded between the substrate body and the cap.

6. The semiconductor device of claim 1, wherein the first and second delta layers are formed by thin layers of phosphorus.

7. The semiconductor device of claim 1, wherein the substrate body and the cap are formed of a semiconductor material.

8. The semiconductor device of claim 1, wherein the first delta layer extends from the source into a region between the substrate body and the cap, and wherein the second delta layer extends from the drain into another region between the substrate body and the cap.

9. The semiconductor device of claim 1, wherein the gap separating the two delta layers is between 2 nano-meters and 12 nano-meters.

10. A semiconductor device having first and second resistive states, comprising:
a substrate body;
a source formed along a first sidewall of the substrate body;
a drain formed along a second sidewall of the substrate body;
first and second delta layers disposed on the substrate body and separated by a gap, wherein the first delta layer is in contact with the source and the second delta layer is in contact with the drain; and
a cap disposed over the first and second delta layers,
wherein the semiconductor device has the first resistive state responsive to a first voltage between the drain and the source and has the second resistive state responsive to a second voltage between the drain and the source.

11. The semiconductor device of claim 10, wherein the semiconductor device has a first resistance in the first resistive state and has a second resistance in the second resistive state.

12. The semiconductor device of claim 11, wherein the first resistance is higher than the second resistance.

13. The semiconductor device of claim 10, wherein the second voltage is higher than the first voltage.

14. The semiconductor device of claim 10, wherein the first voltage is between 0 V and 0.05 V, and wherein the second voltage is between 0.075V and 0.11 V.

15. The semiconductor device of claim 10, wherein the first and second delta layers are formed by thin layers of phosphorus.

16. A method for fabricating a semiconductor device having first and second conductivity regimes, comprising:
forming a substrate body using a semiconductor material;
doping the substrate body to introduce controlled amounts of dopants for controlling electrical properties of the device;
passivating a surface of the substrate body;
forming first and second delta layers on the substrate body, the first and second delta layers separated by a gap;
depositing a cap over the first and second delta layers to embed the delta layers between the substrate body and the cap; and
forming a source in a first region of the substrate body and forming a drain in a second region of the substrate body,
wherein the semiconductor device has the first conductivity regime responsive to a first voltage between the drain and the source and has the second conductivity regime responsive to a second voltage between the drain and the source.

17. The method of claim 16, wherein the second voltage is higher than the first voltage.

18. The method of claim 16, wherein a current between the drain and the source is higher in the second conductivity regime than a current between the drain and the source in the first conductivity regime.

19. The method of claim 16, wherein the first voltage is between 0 V and 0.05 V and the second voltage is between 0.075 V and 0.11 V.

20. The method of claim 16, wherein the substrate body is formed using a crystal silicon wafer.

21. The method of claim 16, wherein the first and second delta layers are formed by thin layers of phosphorus.

22. The method of claim 16, wherein the first delta layer is in contact with the source and the second delta layer is in contact with the drain.
